(19) United States
(12) Patent Application Publication
(10) Pub. No.: US 2024/0213137 A1
(43) Pub. Date: Jun. 27, 2024

(54) PACKAGE SUBSTRATE AND FABRICATING METHOD THEREOF

(71) Applicant: AaltoSemi Inc., Jiangsu (CN)

(72) Inventors: Andrew C. Chang, Jiangsu (CN); Min-Yao Chen, Jiangsu (CN); Yin-Ju Chen, Jiangsu (CN)

(21) Appl. No.: 18/394,736

(22) Filed: Dec. 22, 2023

(30) Foreign Application Priority Data
Dec. 23, 2022 (TW) 111149797

(51) Int. Cl. H01L 23/498; H01L 21/48

(52) U.S. Cl. CPC H01L 23/49894; H01L 21/486; H01L 23/49827

(57) ABSTRACT

A package substrate is provided, in which a first circuit structure is formed on a core board body, and a second circuit structure is formed on the first circuit structure. A second insulating layer of the second circuit structure is made of an ABF material that is different from a material forming a first insulating layer of the first circuit structure, so that a second circuit layer with fine lines/spaces can be formed by the ABF material of the second insulating layer to achieve a purpose of multi-layer fine lines.

### BACKGROUND

### 1. Technical Field

The present disclosure relates to a package substrate for carrying chips, and more particularly, to a package substrate with ABF and a manufacturing method thereof.

### 2. Description of Related Art

Technologies currently used in the field of chip packaging comprise, for example, chip scale package (CSP), direct chip attached (DCA), multi-chip module (MCM), or other types of package modules. As the functional requirements of end products increase, semiconductor chips need to have more input/output (I/O) contacts, so the number of external pads on the package substrate used to carry the semiconductor chips also increases accordingly.

FIG. 1 is a cross-sectional view of a conventional package substrate 1. As shown in FIG. 1, the package substrate 1 comprises a core board body 10 having a first side 10a and a second side 10b opposing the first side 10a, and circuit structures 11 are formed on the first side 10a and the second side 10b of the core board body 10, wherein the circuit structure 11 comprises a plurality of insulating layers 111 and a plurality of circuit layers 110 formed on each of the insulating layers 111, and the core board body 10 has a plurality of conductive vias 100 connecting the first side 10a and the second side 10b to electrically connect the circuit layers 110.

Currently, the circuit structure 11 is manufactured using a conventional build-up process to perform wiring on prepreg (PP) with glass fiber, thereby forming the symmetrical package substrate 1.

However, in the conventional package substrate 1, it is difficult to form the circuit layers 110 with fine lines/spaces since the insulating layers 111 are made with PP material with glass fiber. Therefore, it is difficult for the package substrate 1 to meet the requirement of multi-layer fine lines, resulting in limited functional development of electronic products.

Therefore, there is a need for a solution that addresses the aforementioned shortcomings in the prior art.

### SUMMARY

In view of the aforementioned shortcomings of the prior art, the present disclosure provides a package substrate, which comprises: a core board body having a first side, a second side opposing the first side, and at least one conductive via connecting the first side and the second side: a first circuit structure disposed on the first side of the core board body, wherein the first circuit structure comprises at least one first insulating layer formed on the core board body and a first circuit layer formed on the first insulating layer and electrically connected to the conductive via: and a second circuit structure disposed on the first circuit structure, wherein the second circuit structure comprises at least one second insulating layer formed on the first insulating layer and a second circuit layer formed on the second insulating layer and electrically connected to the first circuit layer, wherein a material forming the second insulating layer is an Ajinomoto build-up film that is different from a material forming the first insulating layer.

The present disclosure also provides a method of manufacturing a package substrate, the method comprises: providing a core board body having a first side and a second side opposing the first side; forming a first circuit structure on the first side of the core board body, wherein the first circuit structure comprises at least one first insulating layer formed on the core board body and a first circuit layer formed on the first insulating layer, wherein the core board body has at least one conductive via connecting the first side and the second side to electrically connect the first circuit layer; and forming a second circuit structure on the first circuit structure, wherein the second circuit structure comprises at least one second insulating layer formed on the first insulating layer and a second circuit layer formed on the second insulating layer and electrically connected to the first circuit layer, wherein a material forming the second insulating layer is an Ajinomoto build-up film that is different from a material forming the first insulating layer.

In the aforementioned package substrate and method, the first circuit structure further comprises a plurality of first conductive blind vias formed in the first insulating layer and electrically connected to the first circuit layer.

In the aforementioned package substrate and method, the conductive via extends into the first circuit structure and is electrically connected to the first circuit layer.

In the aforementioned package substrate and method, the first circuit structure is further formed on the second side of the core board body. Further, the second circuit structure is further formed on the first circuit structure on the second side of the core board body.

As can be understood from the above, in the package substrate and manufacturing method thereof according to the present disclosure, the first insulating layer and the second insulating layer are designed with different materials, such that the first insulating layer made with PP material can provide good rigidity and dimensional stability, and the second insulating layer made with ABF material can be used to form the second circuit layer with fine lines/spaces. Therefore, compared with the prior art, the package substrate of the present disclosure can achieve the purpose of multi-layer fine lines and thinning without warpage.

### BRIEF DESCRIPTION OF THE DRAWINGS

FIG. 1 is a cross-sectional view of a conventional package substrate.

FIG. 2A to FIG. 2F are schematic cross-sectional views illustrating a manufacturing method of a package substrate according to a first embodiment of the present disclosure.

FIG. 3A to FIG. 3E are schematic cross-sectional views illustrating a manufacturing method of a package substrate according to a second embodiment of the present disclosure.

FIG. 4A to FIG. 4D are schematic cross-sectional views illustrating a manufacturing method of a package substrate according to a third embodiment of the present disclosure.

FIG. 5A to FIG. 5D are schematic cross-sectional views illustrating a manufacturing method of a package substrate according to a fourth embodiment of the present disclosure.

FIG. 6A to FIG. 6E are schematic cross-sectional views illustrating a manufacturing method of a package substrate according to a fifth embodiment of the present disclosure.

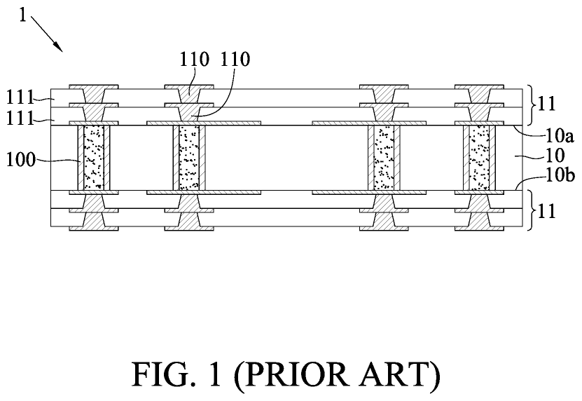

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

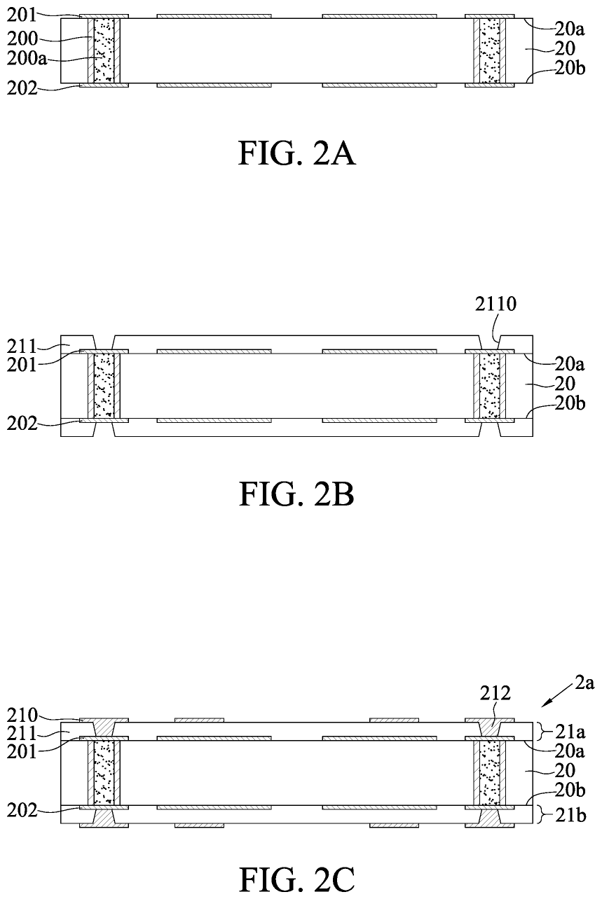

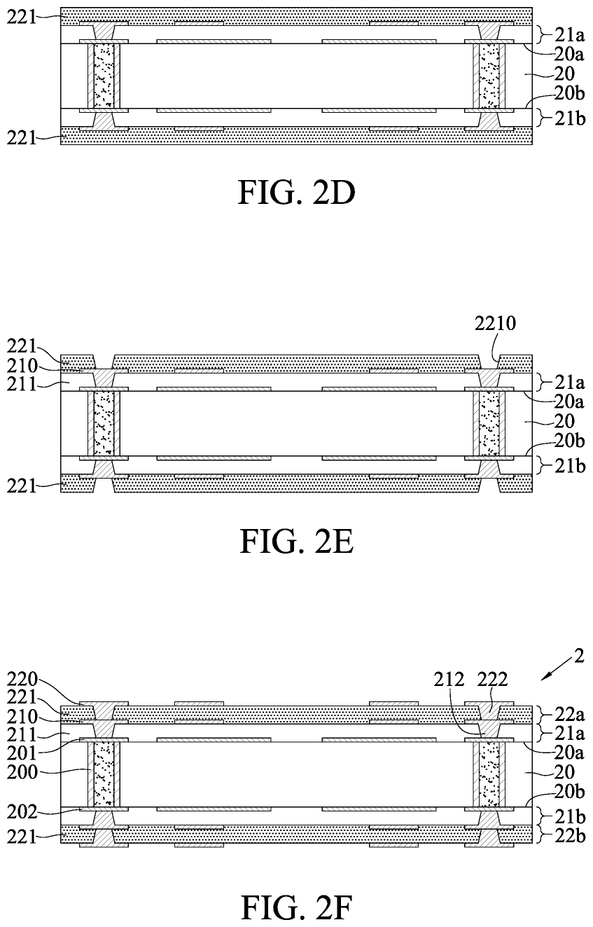

FIG. 2A to FIG. 2F are schematic cross-sectional views illustrating a manufacturing method of a package substrate 2 according to a first embodiment of the present disclosure. As shown in FIG. 2A, a core board body 20 is provided and has a first side 20a and a

second side 20b opposing the first side 20a. An internal circuit layer 201 is formed on the first side 20a of the core board body 20, and an internal circuit layer 202 is formed on the second side 20b of the core board body 20. The core board body 20 has a plurality of conductive vias 200 connecting the first side 20a and the second side 20b, and the conductive vias 200 are electrically connected to the internal circuit layer 201 and the internal circuit layer 202. In an embodiment, the core board body 20 can be made of an organic polymer board

material comprising bismaleimide triazine (BT), prepreg (PP) with glass fiber, or can be made of other board materials. The conductive vias 200 are hollow pillars, which can be filled with plugging material 200a in the hollows. The plugging material 200a can be of various types, such as conductive glue, ink, etc., but is not limited to as such. It should be understood that in other embodiments, the conductive vias 200 can also be solid metal pillars without filling the plugging material 200a.

As shown in FIG. 2B, first insulating layers 211 are respectively formed on the first side 20a and the second side 20b of the core board body 20, for example, by laminating, such that the internal circuit layers 201, 202 are embedded in the first insulating layers 211. Then, a plurality of first openings 2110 are formed on each of the first insulating layers 211 by laser or other methods, so that parts of the surface of the internal circuit layer 201 and parts of the surface of the internal circuit layer 202 are exposed from the first openings 2110.

In an embodiment, each of the first insulating layers 211 is a dielectric layer and made of such as polybenzoxazole (PBO), polyimide (PI), prepreg (PP) with glass fiber, or other dielectric materials.

As shown in FIG. 2C, a patterning process is performed to form a first circuit layer 210 on each of the first insulating layers 211, and a plurality of first conductive blind vias 212 are formed in the first openings 2110 and electrically connected to the internal circuit layers 201, 202 and the first circuit layers 210.

In an embodiment, a build-up process is used to manufacture the first circuit layers 210, the first conductive blind vias 212 and the first insulating layers 211, so that the first circuit layers 210, the first conductive blind vias 212 and the first insulating layers 211 can be served as first circuit structures 21a, 21b, such that the core board body 20, the first circuit structure 21a on the first side 20a of the core board body 20 and the first circuit structure 21b on the second side 20b of the core board body 20 are served as a core structure 2a. For example, the first circuit layer 210 and the first conductive blind vias 212 can be integrally formed by electroplating metal (such as copper) or other methods.

It should be understood that by using the build-up process, the first circuit structures 21a, 21b can add multiple first insulating layers 211 according to requirements so as to manufacture multiple first circuit layers 210.

As shown in FIG. 2D to FIG. 2F, second circuit structures 22a, 22b are formed on the first circuit structures 21a, 21b on opposite sides of the core structure 2a, respectively, thereby forming the symmetrical package substrate 2.

In an embodiment, each of the second circuit structures 22a, 22b comprises at least one second insulating layer 221 formed on the first insulating layer 211, a second circuit layer 220 formed on the second insulating layer 221, and a plurality of second conductive blind vias 222 formed in the second insulating layer 221, so that the second conductive blind vias 222 are electrically connected to the second circuit layer 220 and the first circuit layer 210. For example, each of the second circuit structures 22a, 22b is manufactured by using the build-up process to form a plurality of second openings 2210 on the second insulating layer 221 to expose the first circuit layer 210. Therefore, the second conductive blind vias 222 are also electroplated and formed in the second openings 2210 when the second circuit layer 220 is formed on the second insulating layer 221 by electroplating.

Moreover, a material forming the second insulating layer 221 is different from a material forming the first insulating layer 211. For example, the material forming the second insulating layer 221 is Ajinomoto build-up film (ABF), and the material forming the first insulating layer 211 is prepreg (PP), so the coefficient of thermal expansion (CTE) of the second insulating layer 221 is less than the CTE of the first insulating layer 211. Furthermore, the thickness of the second insulating layer 221 is also less than the thickness of the first insulating layer 211. Even the thickness of the second circuit layer 220 is different from the thickness of the first circuit layer 210.

In addition, the opposite sides of the package substrate 2 have different uses, so the residual copper rates of the second circuit structures 22a, 22b are different. For example, the second circuit structure 22a corresponding to the first side 20a is used as a die mounting side (not shown) for connecting the semiconductor chip, and the second circuit structure 22b corresponding to the second side 20b is used as a ball mounting side (not shown) for connecting the circuit board, so the wiring density on the die mounting side is higher than the wiring density on the ball mounting side. Therefore, the residual copper rate of the outermost second circuit layer 220 of the second circuit structure 22a on the die mounting side is greater than the residual copper rate of the outermost second circuit layer 220 of the second circuit structure 22b on the ball mounting side.

Therefore, the manufacturing method of the present disclosure performs related operations in a symmetrical manner on both upper and lower sides during the manufacturing process. Therefore, even if different materials or dielectric materials with different CTEs are used for build-up operations, the build-up process can still be performed in a material matching and symmetry manner to reduce the warpage of the package substrate 2 during the manufacturing process, so that when the package substrate 2 is connected to a semiconductor chip (not shown) in the subsequent process, the package substrate 2 and the semiconductor chip can be effectively connected to improve the process yield.

Furthermore, a PP material with glass fiber (the first insulating layer 211) is formed on the core board body 20 to provide good rigidity and dimensional stability, and the flip chip ball grid array (FCBGA) type package substrate 2 with multi-layer wiring specification can be manufactured in a symmetry manner. Therefore, even if the copper laying area (or residual copper rate) and copper thickness of each layer of wiring (the first circuit layer 210 and the second circuit layer 220) are different, the occurrence of warpage can still be avoided.

Also, by using an interlayer material (e.g., a dielectric layer material) without glass fiber as a build-up material (such as ABF), and since there is no restriction of glass fiber, it is easier to form smaller laser openings (the second openings 2210) or wiring (the second circuit layer 220) with smaller fine lines/spaces (L/S), and is easier to form thinner second circuit structures 22a, 22b (the second insulating layer 221 or the second circuit layer 220) to achieve the purpose of thinning the overall package substrate 2, such that the package substrate 2 can achieve multi-layer fine line and thin design.

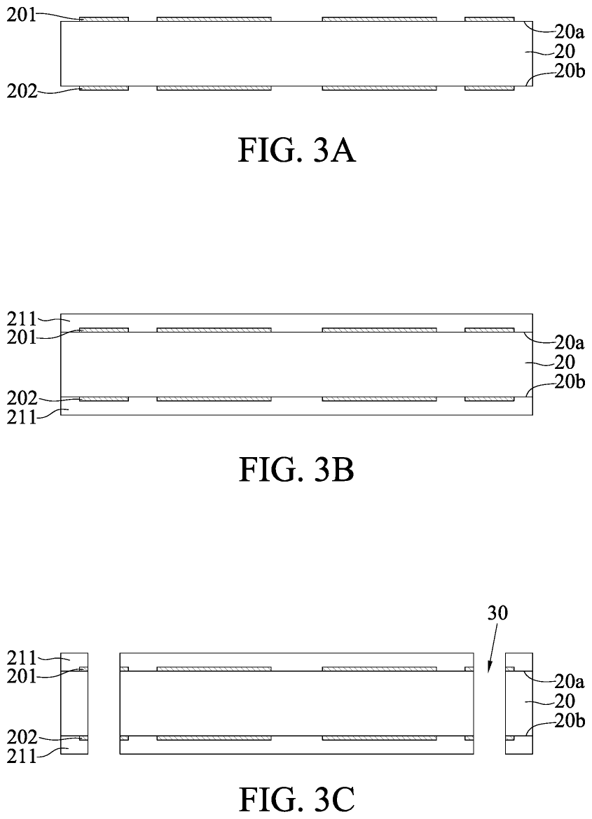

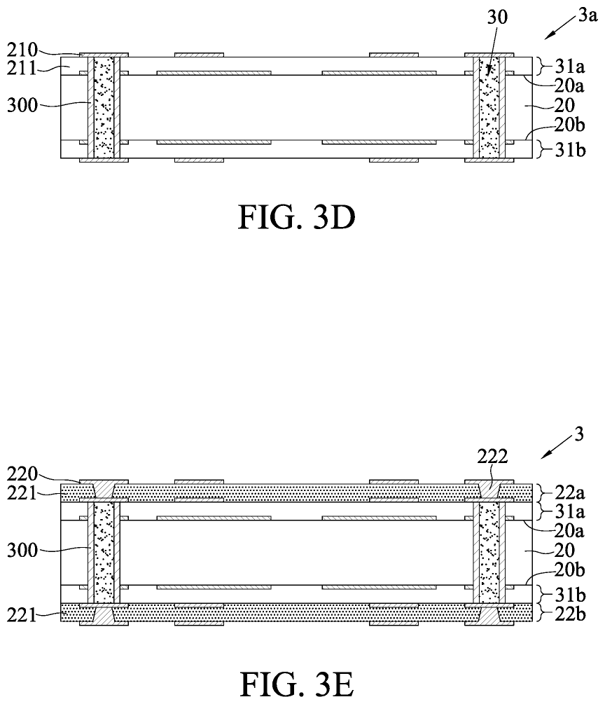

FIG. 3A to FIG. 3E are schematic cross-sectional views illustrating a manufacturing method of a package substrate 3 according to a second embodiment of the present disclosure. The difference between the second embodiment and the first embodiment lies in the manufacturing process of conductive vias 300, while other manufacturing processes are generally the same, so the similarities will not be described again.

As shown in FIG. 3A, the core board body 20 having the first side 20a and the second side 20b opposing the first side 20a is provided, and the internal circuit layers 201, 202 are formed on the first side 20a and the second side 20b of the core board body 20, respectively.

As shown in FIG. 3B, the first insulating layers 211 are respectively formed on the first side 20a and the second side 20b of the core board body 20, for example, by laminating, such that the internal circuit layers 201, 202 are embedded in the first insulating layers 211.

As shown in FIG. 3C, a plurality of through holes 30 penetrating through the core board body 20 and each of the first insulating layers 211 are formed.

In an embodiment, the through holes 30 penetrate through parts of the internal circuit layer 201 on the first side 20a of the core board body 20 and parts of the internal circuit layer 202 on the second side 20b of the core board body 20.

As shown in FIG. 3D, the first circuit layer 210 is formed on each of the first insulating layers 211, and the conductive vias 300 are formed in the through holes 30 and electrically connected to the internal circuit layers 201, 202 and the first circuit layers 210.

In an embodiment, the first conductive blind vias 212 are replaced by the opposite ends of the conductive vias 300, so that the first circuit layers 210 and the first insulating layers 211 are served as first circuit structures 31a, 31b, such that the first circuit structure 31a on the first side 20a of the core board body 20 and the first circuit structure 31b on the second side 20b of the core board body 20 are served as a core structure 3a.

As shown in FIG. 3E, the second circuit structures 22a, 22b are formed on the first circuit structures 31a, 31b on opposite sides of the core structure 3a, respectively, thereby forming the symmetrical package substrate 3.

Therefore, the manufacturing method of the present disclosure performs related operations in a symmetrical manner on both upper and lower sides during the manufacturing process. Therefore, even if different materials or dielectric materials with different CTEs are used for build-up operations, the build-up process can still be performed in a material matching and symmetry manner to reduce the warpage of the package substrate 3 during the manufacturing process, so that when the package substrate 3 is connected to a semiconductor chip (not shown) in the subsequent process, the package substrate 3 and the semiconductor chip can be effectively connected to improve the process yield.

Furthermore, a PP material with glass fiber (the first insulating layer 211) is formed on the core board body 20 made of BT material to provide good rigidity and dimensional stability, and the flip chip ball grid array (FCBGA) type package substrate 3 with multi-layer wiring specification can be manufactured in a symmetry manner. Therefore, even if the copper laying area (or residual copper rate) and copper thickness of each layer of wiring (the first circuit layer 210 and the second circuit layer 220) are different, the occurrence of warpage can still be avoided.

Also, by using an interlayer material (e.g., a dielectric layer material) without glass fiber as a build-up material (such as ABF), and since there is no restriction of glass fiber, it is easier to form smaller laser openings (the second openings 2210) or wiring (the second circuit layer 220) with smaller fine lines/spaces (L/S), and is easier to form thinner second circuit structures 22a, 22b (the second insulating layer 221 or the second circuit layer 220) to achieve the purpose of thinning the overall package substrate 3, such that the package substrate 3 can achieve multi-layer fine line and thin design.

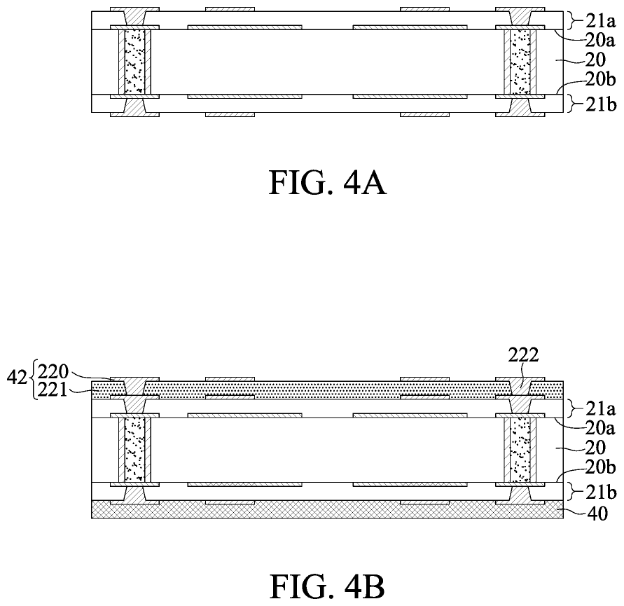

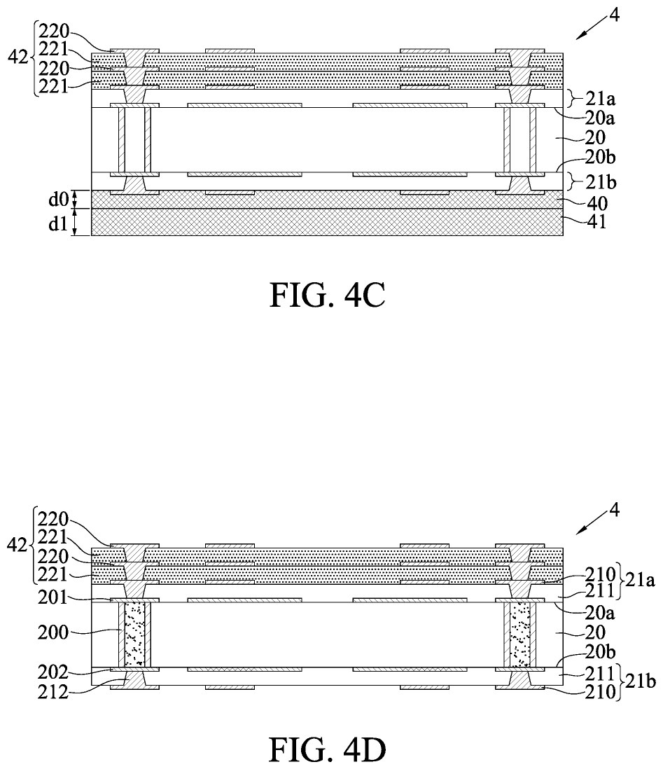

FIG. 4A to FIG. 4D are schematic cross-sectional views illustrating a manufacturing method of a package substrate 4 according to a third embodiment of the present disclosure. The difference between the third embodiment and the first embodiment lies in the manufacturing process of a second circuit structure 42, while other manufacturing processes are generally the same, so the similarities will not be described again.

As shown in FIG. 4A, the core structure 2a shown in FIG. 2D is provided.

As shown in FIG. 4B, a first supporting board 40 is formed on the first circuit structure 21b on one side (such as the second side 20b) of the core structure 2a, and a second circuit structure 42 is formed on the first circuit structure 21a on the other side (such as the first side 20a) of the core structure 2a.

In an embodiment, the second circuit structure 42 comprises at least one second insulating layer 221, the second circuit layer 220 formed on the second insulating layer 221, and the plurality of second conductive blind vias 222 formed in the second insulating layer 221, so that the second conductive blind vias 222 are electrically connected to the second circuit layer 220 and the first circuit layer 210. For example, the second circuit structure 42 is manufactured by using the build-up process, so the second insulating layer 221 and the first supporting board 40 can be laminated simultaneously on the first side 20a and the second side 20b of the core structure 2a respectively, and then the second circuit layer 220 and the second conductive blind vias 222 are fabricated.

Moreover, multiple second circuit layers 220 can be formed according to requirements, as shown in FIG. 4C. Therefore, before adding a layer of the second circuit layer 220, another second insulating layer 221 and a second supporting board 41 can be laminated on the first side 20a and the second side 20b of the core structure 2a respectively to balance the stress on the opposite sides of the core structure 2a, thereby preventing the core structure 2a from warpage during the manufacturing process. Furthermore, the thicknesses of the supporting boards can be different, for example, a thickness d1 of the second supporting board 41 on the outside is greater than a thickness do of the first supporting board 40 on the inside, so as to facilitate suppressing warpage.

Also, the material forming the first supporting board 40 and the second supporting board 41 can be epoxy resin, PI, flame resistant/retardant 4 (FR4), metal, or other recyclable materials with rigid support.

As shown in FIG. 4D, the first supporting board 40 and the second supporting board 41 are removed to obtain the asymmetric package substrate 4.

Therefore, the manufacturing method of the present disclosure avoids warpage problems due to the asymmetric structure during the process of laminating the second insulating layer 221 by the design of the first supporting board 40 and the second supporting board 41.

Furthermore, a PP material with glass fiber is used as the material of the core structure 2a to maintain the stability and thermal stability of the predetermined size, and is combined with a dielectric layer (the second insulating layer 221) that is without glass fiber and served as a build-up material (such as ABF) so as to facilitate the wiring (the second circuit layer 220) process of fine lines and micro-holes, so that the package substrate 4 can realize the design of multi-layer thin lines and thinning.

In addition, the first supporting board 40 and the second supporting board 41 of recyclable materials with corresponding thicknesses are served as supporting members to avoid warpage during the manufacturing process, thereby eliminating the need to use conventional extremely thick temporary carrier (such as copper foil substrate), resulting in significant material cost savings.

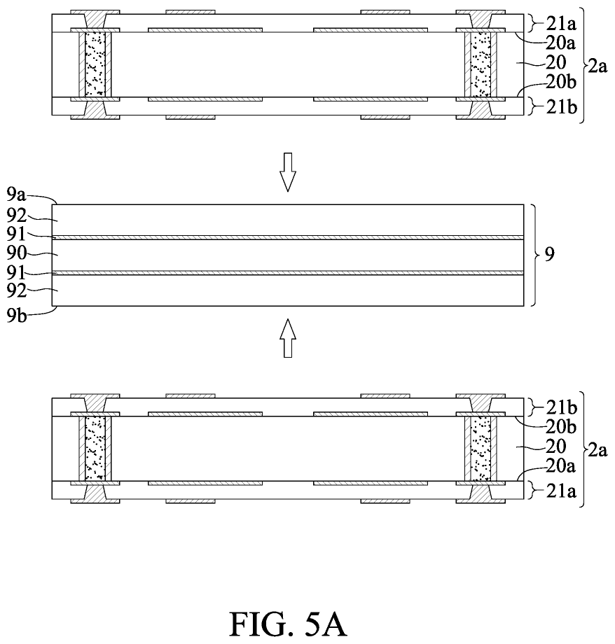

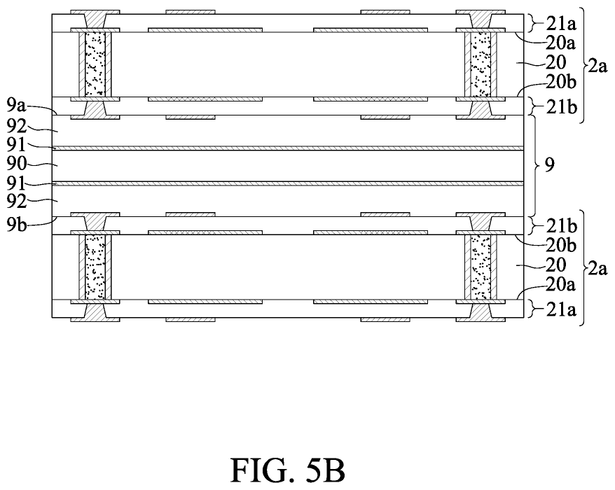

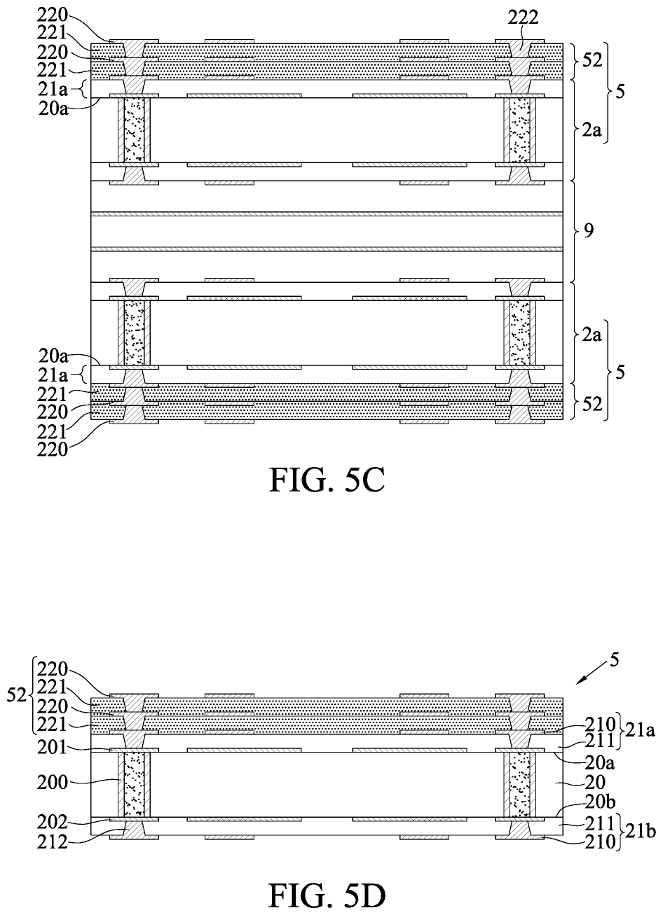

FIG. 5A to FIG. 5D are schematic cross-sectional views illustrating a manufacturing method of a package substrate 5 according to a fourth embodiment of the present disclosure. The difference between the fourth embodiment and the aforementioned embodiments lies in production method, while other manufacturing processes are generally the same, so the similarities will not be described again.

As shown in FIG. 5A, a carrier 9 and a plurality of the core structures 2a shown in FIG. 2D are provided, wherein the carrier 9 has a first surface 9a and a second surface 9b opposing the first surface 9a.

In an embodiment, the carrier 9 is a temporary carrier board, and a board body 90 of the carrier 9 can be a copper foil substrate or made of other board materials. For example, the carrier 9 is a copper foil substrate and comprises copper foil 91, and a release layer 92 such as a dielectric layer can be formed on the copper foil 91 according to requirements.

As shown in FIG. 5B, the core structures 2a are symmetrically formed on the first surface 9a and the second surface 9b of the carrier 9 in a manner of lamination, so that the core structure 2a is bonded to the release layer 92 via the first circuit structure 21b of the second side 20b thereof, and the first circuit structure 21a on the first side 20a of the core structure 2a faces outward.

In an embodiment, the release layer 92 covers the first circuit layer 210 of the first circuit structure 21b of the second side 20b, so that the first circuit layer 210 of the first circuit structure 21b of the second side 20b is embedded in the release layer 92.

As shown in FIG. 5C, a second circuit structure 52 is formed on the first circuit structure 21a on the first side 20a of each of the core structures 2a.

In an embodiment, the second circuit layers 220, the second conductive blind vias 222 and the second insulating layers 221 are served as the second circuit structure 52, so that the second circuit structure 52 is similar to the second circuit structure 42 shown in FIG. 4C. For example, the second circuit structure 52 is manufactured by using the build-up process, so the second insulating layers 221 can be laminated simultaneously on the first side 20a and the second side 20b of the core structure 2a, and then the second circuit layers 220 and the second conductive blind vias 222 are fabricated.

As shown in FIG. 5D, the carrier 9 is removed to obtain a plurality of the package substrates 5, and the structure of the package substrate 5 is as the asymmetric package substrate 4 shown in FIG. 4D.

Therefore, the manufacturing method of the present disclosure simultaneously laminates the second insulating layers 221 on opposite sides of the carrier 9 to avoid warpage problems due to the asymmetric structure.

Furthermore, related operations can be performed on the first surface 9a and the second surface 9b of the carrier 9 simultaneously during the process of manufacturing the package substrate 5 by using the carrier 9, thereby increasing productivity.

Also, a PP material with glass fiber is used as the material of the core structure 2a to maintain the stability and thermal stability of the predetermined size, and is combined with a dielectric layer (the second insulating layer 221) that is without glass fiber and served as a build-up material (such as ABF) so as to facilitate the wiring (the second circuit layer 220) process of fine lines and micro-holes, so that the package substrate 5 can realize the design of multi-layer thin lines and thinning.

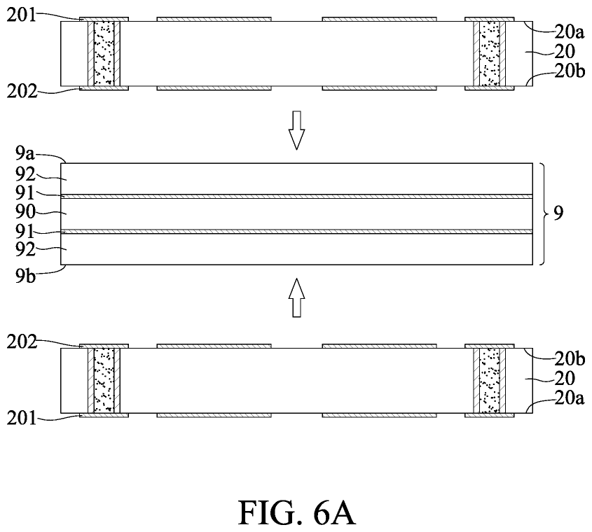

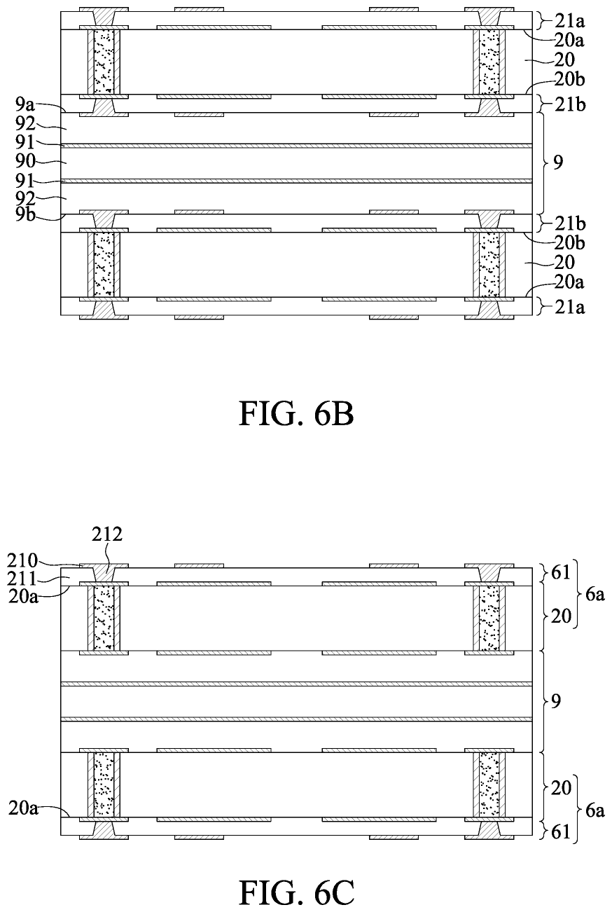

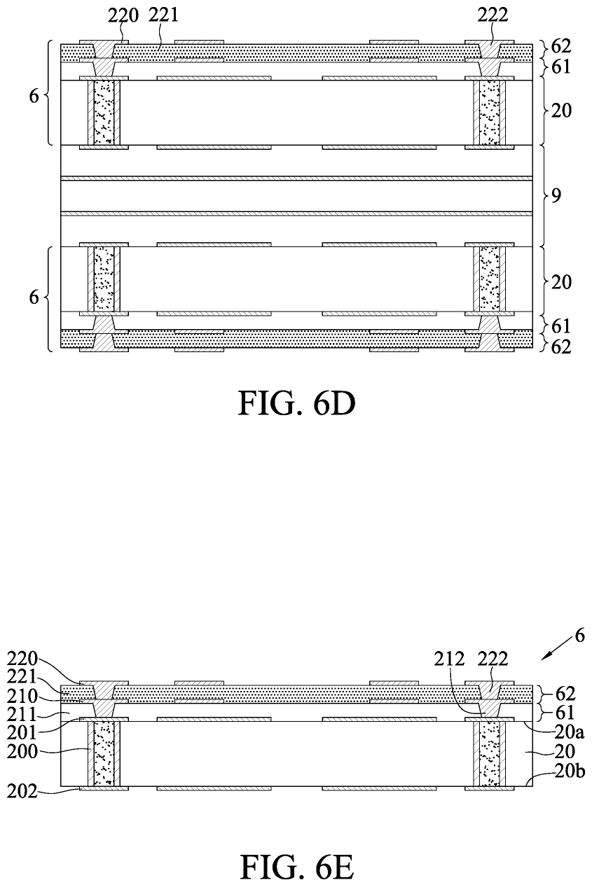

FIG. 6A to FIG. 6E are schematic cross-sectional views illustrating a manufacturing method of a package substrate 6 according to a fifth embodiment of the present disclosure. The difference between the fifth embodiment and the fourth embodiment lies in lamination process, while other manufacturing processes are generally the same, so the similarities will not be described again.

As shown in FIG. 6A, the carrier 9 and a plurality of the core board bodies 20 shown in FIG. 2A are provided.

As shown in FIG. 6B, the core structures 2a and the core board bodies 20 are symmetrically formed on the first surface 9a and the second surface 9b of the carrier 9 in a manner of lamination, so that the core board body 20 is bonded to the release layer 92 via the second side 20b thereof, and the first side 20a of the core board body 20 faces outward.

In an embodiment, the release layer 92 covers the internal circuit layer 202 of the second side 20b of the core board body 20, so that the internal circuit layer 202 is embedded in the release layer 92.

As shown in FIG. 6C, a first circuit structure 61 is formed on the first side 20a of each of the core board bodies 20.

In an embodiment, the first circuit layer 210, the first conductive blind vias 212 and the first insulating layer 211 are served as the first circuit structure 61, so that the first circuit structure 61 is similar to the first circuit structure 21a shown in FIG. 2C, such that the core board body 20 and the first circuit structure 61 on the first side 20a of the core board body 20 are served as a core structure 6a.

As shown in FIG. 6D, a second circuit structure 62 is formed on the first circuit structure 61 of each of the core structures 6a.

In an embodiment, the second circuit layer 220, the second conductive blind vias 222 and the second insulating layer 221 are served as the second circuit structure 62, so that the second circuit structure 62 is similar to the second circuit structure 22a shown in FIG. 2F.

As shown in FIG. 6E, the carrier 9 is removed to obtain a plurality of the asymmetric package substrates 6, and the internal circuit layer 202 of the second side 20b of the core board body 20 is exposed.

Therefore, the manufacturing method of the present disclosure simultaneously laminates the second insulating layers 221 on opposite sides of the carrier 9 to avoid warpage problems due to the asymmetric structure.

Furthermore, related operations can be performed on the first surface 9a and the second surface 9b of the carrier 9 simultaneously during the process of manufacturing the package substrate 6 by using the carrier 9, thereby increasing productivity.

Also, a PP material with glass fiber is used as the material of the core board body 20 and the first insulating layer 211 to maintain the stability and thermal stability of the predetermined size, and is combined with a dielectric layer (the second insulating layer 221) that is without glass fiber and served as a build-up material (such as ABF) so as to facilitate the wiring (the second circuit layer 220) process of fine lines and micro-holes, so that the package substrate 6 can realize the design of multi-layer thin lines and thinning.

On the other hand, it can be seen from the third to fifth embodiments that the package substrates 4, 5, 6 of the present disclosure have a high degree of design freedom and can arbitrarily combine the circuit structures with various wiring specifications according to requirements.

The present disclosure also provides a package substrate 2, 3, 4, 5, 6, which comprises: a core board body 20 having a first side 20a and a second side 20b opposing the first side 20a, a first circuit structure 21a, 31a, 61 disposed on the first side 20a of the core board body 20, and a second circuit structure 22a, 42, 52, 62 disposed on the first circuit structure 21a, 31a, 61.

The core board body 20 has at least one conductive via 200, 300 connecting the first side 20a and the second side 20b.

The first circuit structure 21a, 31a, 61 comprises at least one first insulating layer 211 formed on the core board body 20 and a first circuit layer 210 formed on the first insulating layer 211 and electrically connected to the conductive via 200, 300.

The second circuit structure 22a, 42, 52, 62 comprises at least one second insulating layer 221 formed on the first insulating layer 211 and a second circuit layer 220 formed on the second insulating layer 221 and electrically connected to the first circuit layer 210, and a material forming the second insulating layer 221 is an Ajinomoto build-up film that is different from a material forming the first insulating layer 211.

In one embodiment, the first circuit structure 21a, 61 further comprises a plurality of first conductive blind vias 212 disposed in the first insulating layer 211 and electrically connected to the first circuit layer 210.

In one embodiment, the conductive via 300 extends into the first circuit structure 21 and is electrically connected to the first circuit layer 210.

In one embodiment, the first circuit structure 21b, 31b is further formed on the second side 20b of the core board body 20. Further, the second circuit structure 22b is further formed on the first circuit structure 21b, 31b on the second side 20b of the core board body 20, thereby forming the symmetrical package substrate 2, 3.

In view of the above, in the package substrate and manufacturing method thereof according to the present disclosure, the first insulating layer and the second insulating layer are designed with different materials, such that the first insulating layer made with PP material can provide good rigidity and dimensional stability, and the second insulating layer made with ABF material can be used to form the second circuit layer with fine lines/spaces. Therefore, compared with the prior art, the package substrate of the present disclosure can achieve the purpose of multi-layer fine lines and thinning without warpage.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core board body having a first side, a second side opposing the first side, and at least one conductive via connecting the first side and the second side:
a first circuit structure disposed on the first side of the core board body, and comprising at least one first insulating layer formed on the core board body and a first circuit layer formed on the first insulating layer and electrically connected to the conductive via; and
a second circuit structure disposed on the first circuit structure, and comprising at least one second insulating layer formed on the first insulating layer and a second circuit layer formed on the second insulating layer and electrically connected to the first circuit layer, wherein a material forming the second insulating layer is an Ajinomoto build-up film that is different from a material forming the first insulating layer.

2. The package substrate of claim 1, wherein the first circuit structure further comprises a plurality of first conductive blind vias formed in the first insulating layer and electrically connected to the first circuit layer.

3. The package substrate of claim 1, wherein the conductive via extends into the first circuit structure and is electrically connected to the first circuit layer.

4. The package substrate of claim 1, wherein the first circuit structure is further formed on the second side of the core board body.

5. The package substrate of claim 2, wherein the second circuit structure is further formed on the first circuit structure on the second side of the core board body.

6. A method of manufacturing a package substrate, comprising:
providing a core board body having a first side and a second side opposing the first side:
forming a first circuit structure on the first side of the core board body, wherein the first circuit structure comprises at least one first insulating layer formed on the core board body and a first circuit layer formed on the first insulating layer, wherein the core board body has at least one conductive via connecting the first side and the second side to electrically connect the first circuit layer; and
forming a second circuit structure on the first circuit structure, wherein the second circuit structure comprises at least one second insulating layer formed on the first insulating layer and a second circuit layer formed on the second insulating layer and electrically connected to the first circuit layer, wherein a material forming the second insulating layer is an Ajinomoto build-up film that is different from a material forming the first insulating layer.

7. The method of claim 6, wherein the first circuit structure further comprises a plurality of first conductive blind vias formed in the first insulating layer and electrically connected to the first circuit layer.

8. The method of claim 6, wherein the conductive via extends into the first circuit structure and is electrically connected to the first circuit layer.

9. The method of claim 6, wherein the first circuit structure is further formed on the second side of the core board body.

10. The method of claim 9, wherein the second circuit structure is further formed on the first circuit structure on the second side of the core board body.
